(19) United States
(12) Patent Application Publication
(10) Pub. No.: US 2018/0323172 A1
(43) Pub. Date: Nov. 8, 2018

(54) ELIMINATING DIE SHADOW EFFECTS BY DUMMY DIE BEAMS FOR SOLDER JOINT RELIABILITY IMPROVEMENT

(71) Applicant: Intel Corporation, Santa Clara, CA (US)

(72) Inventors: Mao GUO, Shanghai (CN); Sireesha GOGINENI, Folsom, CA (US)

(21) Appl. No.: 15/772,478

(22) PCT Filed: Dec. 22, 2015
(86) PCT No.: PCT/CN2015/098161

§ 371 Date: Apr. 30, 2018

(51) Int. Cl. H01L 25/065; H01L 25/00; H01L 23/13; H01L 23/00

(52) U.S. Cl. CPC H01L 25/0657; H01L 25/50; H01L 23/13; H01L 2224/48227; H01L 2225/0651; H01L 2225/06562; H01L 24/48

(57) ABSTRACT

A package with improved solder joint reliability is disclosed. The package includes dummy beams with less rigidity and stiffness (relative to the die) that are placed in between the die and the substrate. The reduced rigidity and stiffness of the dummy beams significantly mitigates any die shadow effects on the solder joints. Also, because the die is attached to the dummy beams and does not directly contact the substrate itself, the die shadow effect from a rigid die is further reduced.

### BACKGROUND

### Field

Embodiments are related in general to semiconductor device packaging and, in particular, to substrate packages upon which an integrated circuit (IC) chip (e.g., “chips”, “dies”, “ICs” or “IC chips”) may be directly attached, and methods for their manufacture.

### Description of Related Art

Integrated circuit (IC) chips, such as microprocessors, coprocessors, and other microelectronic devices often use package devices (“packages”) to physically and/or electronically attach the IC chip to a printed circuit board (e.g. “PCB”), such as a motherboard (or motherboard interface). The IC chip (e.g., “die”) is typically mounted within a microelectronic substrate package that, among other functions, enables electrical connections between the die and a socket, a motherboard, or another next-level component.

When a bottom die of multiple stacked dies on a substrate is smaller in area relative to the substrate size and the package size, solder balls (“solder joints,” or “signal pins”) underneath a die edge of the bottom die are at risk of early solder joint failure during board level reliability testing. For a package utilizing a signal pin scheme in such manner that the functionally critical pins rest under the bottom die edge, this can translate to early failures of the component impacting the overall product reliability. A die shadow effect is caused by higher shear stress on the solder joints at the bottom die edge due to coefficient of thermal expansion (“CTE”) mismatch between the die and the substrate on which the package is surface mounted.

### BRIEF DESCRIPTION OF THE DRAWINGS

The embodiments are illustrated by way of example and not by way of limitation in the figures of the accompanying drawings in which like references indicate similar elements. It should be noted that references to “an” or “one” embodiment in this disclosure are not necessarily to the same embodiment, and they mean at least one.

FIG. 1 shows a representation of a mechanical simulation of a package according to an embodiment of an invention.

FIG. 2 is a schematic side-cross sectional view of the package shown in FIG. 1.

FIG. 3 represents results of a mechanical simulation of another embodiment of the package.

FIGS. 4a and 4b show representations of mechanical simulations of a package with and without the use of dummy beams.

FIG. 5 is a flow chart illustrating a process for forming a package, according to embodiments described herein.

FIG. 6 illustrates a computing device in accordance with one implementation.

### DETAILED DESCRIPTION

Several embodiments with reference to the appended drawings are now explained. Whenever the shapes, relative positions and other aspects of the parts described in the embodiments are not clearly defined, the scope of embodiments is not limited only to the parts shown, which are meant merely for the purpose of illustration. Also, while numerous details are set forth, it is understood that some embodiments may be practiced without these details. In other instances, well-known circuits, structures, and techniques have not been shown in detail so as not to obscure the understanding of this description.

Presented herein is a solution to address the die shadow effect which may cause solder joint degradation or failure in semiconductor device packages. The die shadow effect is problematic when a die (or multiple stacked dies), which is smaller in area relative to the substrate and the package, is directly attached to a substrate. Typically, solder balls underneath a die (usually within about two ball pitches of an edge of the die) are functionally critical, while solder balls outside about two ball pitches of the edges of the die are not as functionally critical. Solder joints on a bottom surface of the substrate, located directly below the edges or the corners of the bottom-most die are at higher risk of degradation or failure. The risk of solder joint degradation or failure is further exacerbated as the size of the bottom die gets smaller relative to the package size. As the bottom-most die increases in area, the risk of solder joint degradation or failure is lessened.

The solution makes use of dummy beams with less rigidity and stiffness (relative to the die) that are placed in between the die and the substrate. It has been observed that the reduced rigidity and stiffness of the dummy beams significantly mitigates the die shadow effect. Also, because the die is attached to the dummy beams and does not directly contact the substrate itself, the die shadow effect from a small rigid die, for example, is eliminated or significantly reduced.

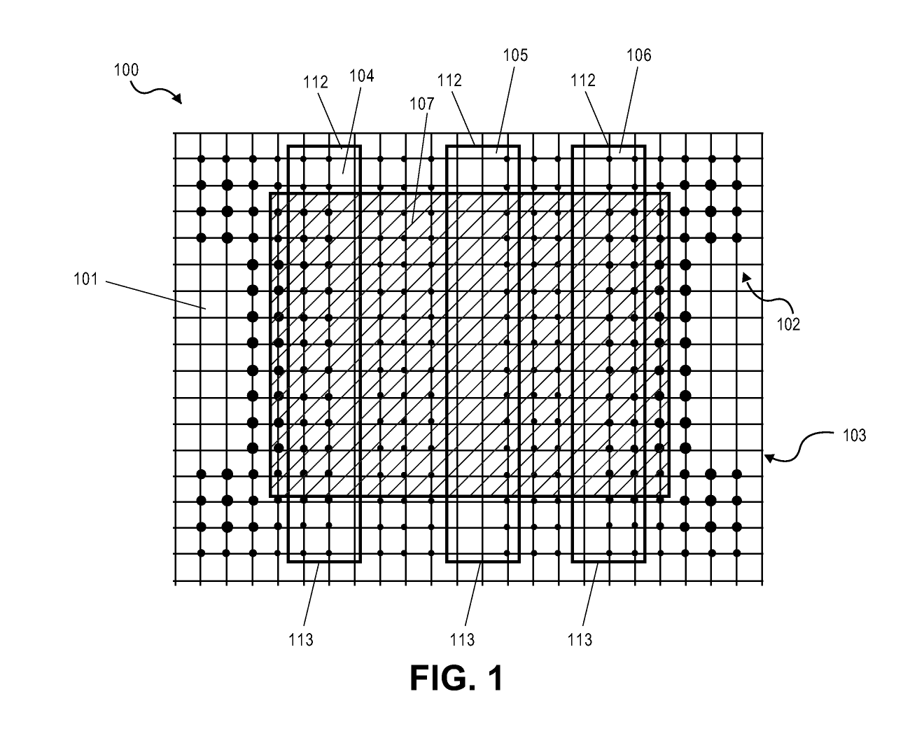

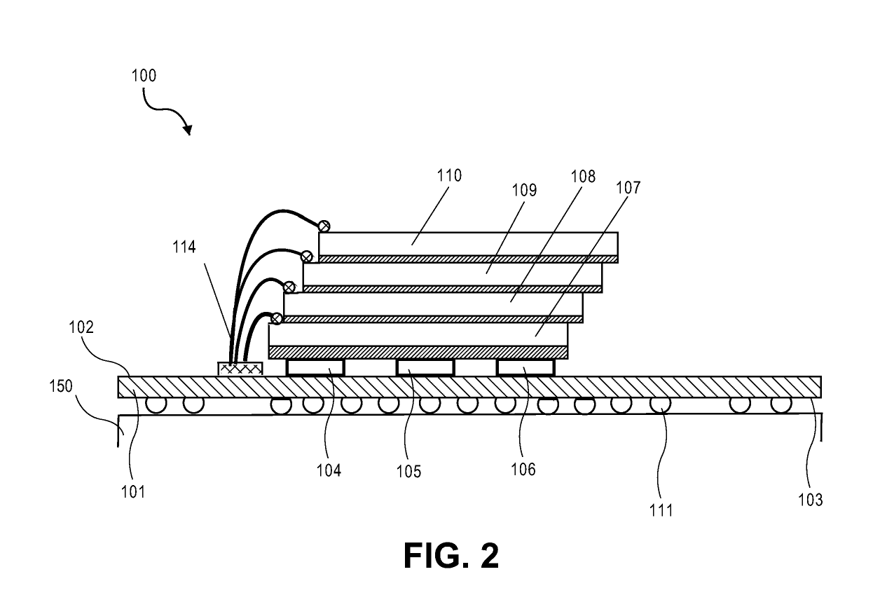

FIG. 1 represents results of a mechanical simulation of a package. FIG. 2 is a schematic side-cross sectional view of the package shown in FIG. 1. In this embodiment, the package has further improvements to its solder joint reliability (“SJR”) through the use of dummy beams in between die(s) and a substrate. Package 100 includes substrate 101 with a top surface 102 and an opposite bottom surface 103. The bottom surface 103 may have one or more contacts. In this embodiment, three dummy beams 104, 105 and 106 are evenly placed on the top surface 102 of the substrate 101 so that they are essentially parallel to each other and spaced apart a similar distance from one another. A die 107 may be placed on top of the dummy beams 104-106. Additional dies 108, 109 and 110 may be placed on top of the die 107 in a stacked configuration. The dummy beams 104-106 are placed on the substrate 101 so that the die 107 does not directly contact the substrate 101. Solder balls 111 may be formed to contacts on the bottom surface 103 of the substrate 101 that can be used to connect package 100 to substrate 150 such as a printed circuit board. Wire bonds 114 may connect the dies 107-110 to the substrate 101.

In one embodiment, each dummy beam 104-106 may be made of silicon and shaped as a rectangle. In another embodiment, dummy beams 104-106 may have another cross-sectional shape (e.g. trapezoid, parallelogram). A representative thickness, t, of dummy beams 104-106 is on the order of 30 to 80 microns, depending on the size of the overall package and the die(s). It is preferred that the dummy beams 104-106 have less rigidity and stiffness than the die 107, for example, because this minimizes the impact of the die shadow effect and significantly lessens shear deformation and degradation of the solder balls 111 on the bottom surface 103 of the substrate 101, below the edges of the dummy beams 104-106. In one embodiment, less rigidity of the dummy beams 104-106 may be achieved by having a reduced thickness of the dummy beams 104-106 relative to the thickness of the dies 107-110. In another embodiment, less rigidity of the dummy beams 104-106 may be achieved by having a smaller width of the dummy beams 104-106 relative to a length and a width of the dies 107-110.

The length and width of the dummy beams 104-106 may vary. In the embodiment of FIG. 1, each dummy beam 104-106 has a length greater than its width. This embodiment also shows that the length of the dummy beams 104-106 is greater than the sides (i.e. length and width) of the die 107. Each dummy beam 104-106 may have a first end 112 and a second end 113 along the length of the dummy beam 104-106. When the die 107 is placed on top of the dummy beams 104-106, the die 107 and the dummy beams 104-106 are positioned so that a portion of each of the dummy beams 104-106 extends beyond an edge of the die 107. For example, the first end 112 extends beyond one edge of the die 107 and the second end 113 extends beyond an opposite edge of the die 107. This allows each dummy beam 104-106 to extend beyond one edge of the die 107 as well as the edge on the opposite side of the die 107 as shown in FIG. 1.

FIG. 1 also shows an embodiment where the length of the dummy beams 104-106 are essentially parallel to the width of the substrate 101 and the width of the die 107. In this embodiment, the length of the dummy beams 104-106 are essentially perpendicular to the length of the substrate 101 and the length of the die 107. In another embodiment, dummy beams 104-106 are not parallel to the width of die 107 and/or substrate 101.

In some cases, the length of each dummy beam 104-106 may be less than each side of the substrate 101. In some cases, as shown in FIG. 1, the length of each dummy beam 104-106 may be less than the length of the substrate 101. In some cases, as shown in FIG. 1, the length of each dummy beam 104-106 may be less than the width of the substrate 101. In some cases, the length of each dummy beam 104-106 may be greater than the width of the substrate 101.

In some cases, the length of each dummy beam 104-106 may be greater than each side of the die 107. In some cases, the length of each dummy beam 104-106 may be greater than the length of the die 107. In some cases, the length of each dummy beam 104-106 may be less than the length of the die 107. In some cases, as shown in FIG. 1, the length of each dummy beam 104-106 may be greater than the width of the die 107.

In some cases, the length of each side of the die 107 is less than the length of each side of the substrate 101. In some cases, as shown in FIG. 1, the length of the die 107 is less than the length of the substrate 101. In some cases, the length of the die 107 is less than the width of the substrate 101. In some cases, as shown in FIG. 1, the width of the die 107 is less than the width of the substrate 101.

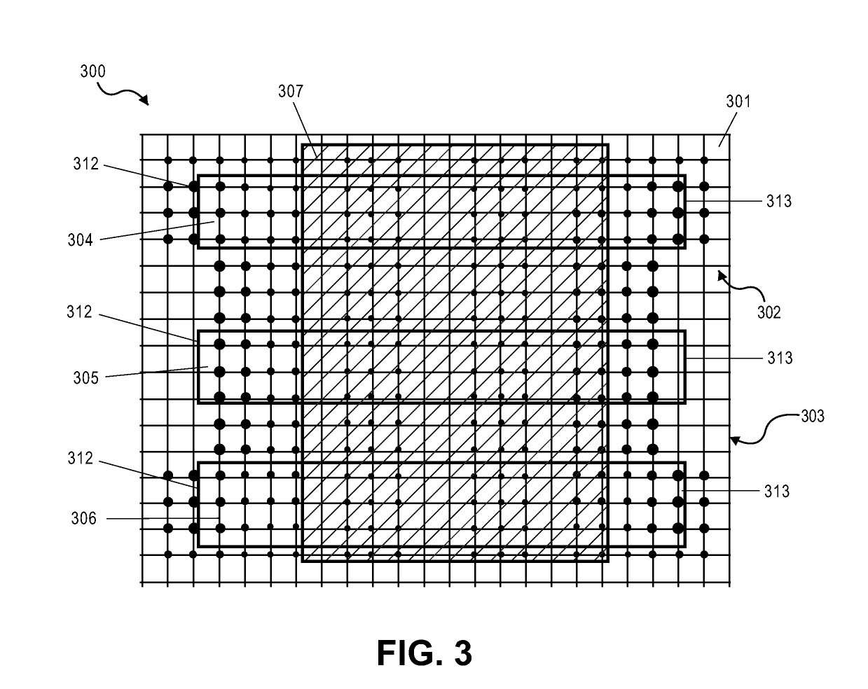

FIG. 3 represents results of a mechanical simulation of another embodiment of the package that is similar to the package 100 shown in FIGS. 1 and 2. Package 300 has a substrate 301 with a top surface 302 and an opposite bottom surface 303. The bottom surface 303 may have one or more contacts. In this embodiment, three dummy beams 304, 305 and 306 are evenly placed on the top surface 302 of the substrate 301 so that they are essentially parallel to each other and spaced apart. A die 307 may be placed on top of the dummy beams 304-306. Additional dies 308, 309 and 310 may be placed on top of the die 307. The dummy beams 304-306 are placed on the substrate 301 so that the die 307 does not directly contact the substrate 301. Solder balls 311 may be formed on the bottom surface 303 of the substrate 301. This embodiment is similar to that shown in FIGS. 1 and 2, except that here, the length of the dummy beams 304-306 are essentially parallel to the length of the substrate 301 and the width of the die 307. In this embodiment, the length of the dummy beams 304-306 are essentially perpendicular to the width of the substrate 301 and the length of the die 307.

In this embodiment, each dummy beam 304-306 may be made of silicon and shaped as a rectangle. In another embodiment, dummy beams 304-306 may have another cross-sectional shape (e.g. trapezoid, parallelogram). A representative thickness, t, of dummy beams 304-306 is on the order of 30 to 80 microns, depending on the size of the overall package and the die(s). It is preferred that the dummy beams 304-306 have less rigidity and stiffness than the die 307, for example, because this minimizes the impact of the die shadow effect and significantly lessens shear deformation and degradation of the solder balls 311 on the bottom surface 303 of the substrate 301, below the edges of the dummy beams 304-306. In one embodiment, less rigidity of the dummy beams 304-306 may be achieved by having a reduced thickness of the dummy beams 304-306 relative to the thickness of the dies 307-310. In another embodiment, less rigidity of the dummy beams 304-306 may be achieved by having a smaller width of the dummy beams 304-306 relative to a length and a width of the dies 307-310

The length and width of the dummy beams 304-306 may vary. In the embodiment of FIG. 3, each dummy beam 304-306 has a length greater than its width. This embodiment also shows that the length of the dummy beams 304-306 is greater than the sides (i.e. length and width) of the die 307. Each dummy beam 304-306 may have a first end 312 and a second end 313 along the length of the dummy beam 304-306. When the die 307 is placed on top of the dummy beams 304-306, the die 307 and the dummy beams 304-306 are positioned so that a portion of each of the dummy beams 304-306 extends beyond an edge of the die 307. For example, the first end 312 extends beyond one edge of the die 307 and the second end 313 extends beyond an opposite edge of the die 307. This allows each dummy beam 304-306 to extend beyond one edge of the die 307 as well as the edge on the opposite side of the die 307 as shown in FIG. 3.

FIG. 3 also shows an embodiment where the length of the dummy beams 304-306 are essentially parallel to the length of the substrate 301 and the width of the die 307. In this embodiment, the length of the dummy beams 304-306 are essentially perpendicular to the width of the substrate 301 and the length of the die 307. In another embodiment, dummy beams 304-306 are not parallel or perpendicular to the edges of die 307 and/or substrate 301.

In some cases, the length of each dummy beam 304-306 may be less than each side of the substrate 301. In some cases, as shown in FIG. 3, the length of each dummy beam 304-306 may be less than the length of the substrate 301. In some cases, the length of each dummy beam 304-306 may be less than the width of the substrate 301. In some cases, the length of each dummy beam 304-306 may be greater than the width of the substrate 301.

In some cases, the length of each dummy beam 304-306 may be greater than each side of the die 307. In some cases, the length of each dummy beam 304-306 may be greater than the length of the die 307. In some cases, the length of each dummy beam 304-306 may be less than the length of the die 307. In some cases, as shown in FIG. 3, the length of each dummy beam 304-306 may be greater than the width of the die 307.

In some cases, the length of each side of the die 307 is less than the length of each side of the substrate 301. In some cases, as shown in FIG. 3, the length of the die 307 is less than the length of the substrate 301. In some cases, the length of the die 307 is less than the width of the substrate 301. In some cases, the width of the die 307 is less than the width of the substrate 201.

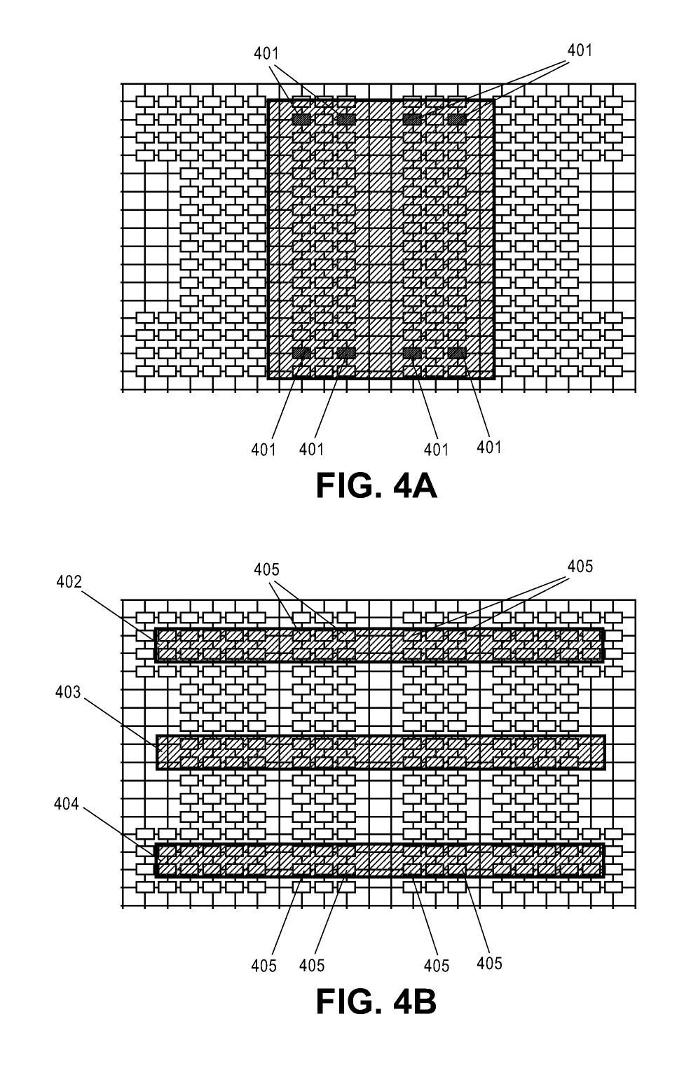

FIGS. 4a and 4b show representations of mechanical simulations comparing a standard package without dummy beams (FIG. 4a) with a package using dummy beams (FIG. 4b) (e.g. package 100, 300 described above). Normalized fatigue life in temperature cycling shows an improved solder joint life with dummy beams than without. FIG. 4a shows solder balls 401 that are likely to be subject to degradation or failure after temperature cycling due to the die shadow effect. FIG. 4b shows that when dummy beams 402, 403, and 404 are used, solder balls 405 underneath the substrate, which are in the same position as solder balls 401 of FIG. 4a, are not subject to degradation or failure. Mechanical simulations have shown that the use of dummy beams 402-404 resulted in approximately 50% improvement in solder joint life. Solder joint life improvement of up to 1.5× is feasible based on the size, quantity and orientation of the dummy die beams depending on the ballout.

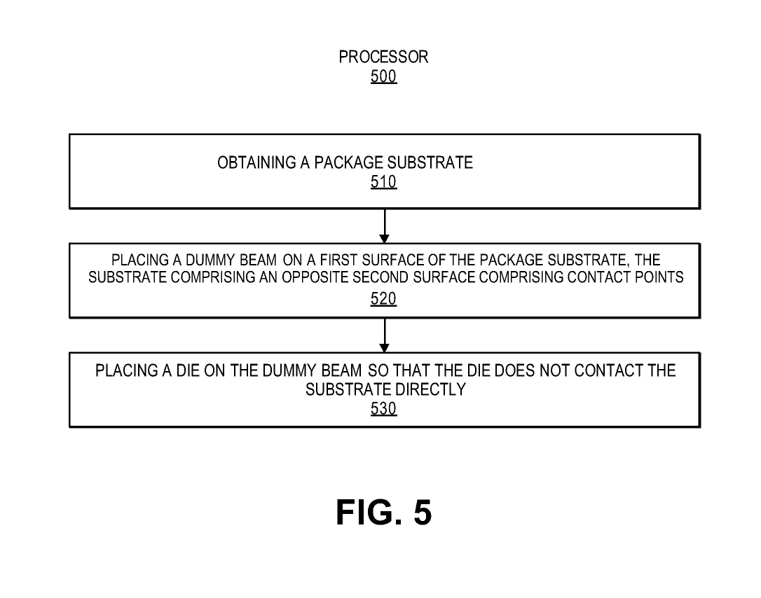

FIG. 5 is a flow chart illustrating a process for forming a package according to embodiments described herein. FIG. 5 shows process 500 which may be a process for forming embodiments described herein of packages 100, 300 of FIGS. 1 and 2.

Process 500 begins at block 510 at which a package substrate 101 is obtained. The substrate 101 may be a substrate used in an electronic device package or a microprocessor package. After the substrate 101 is obtained at block 510, one or more dummy beams may be placed on the top surface 102 of the substrate 101 at block 520. There may be two dummy beams. There may be three or more dummy beams. The substrate 101 may have an opposite bottom surface 103 with contact points. In this embodiment, there may be three dummy beams 104-106 placed on the substrate 101. The dummy beams 104-106 may be placed essentially parallel to and spaced apart from each other. At block 530, a die 107 may be placed on top of the dummy beams 104-106 so that the die 107 does not contact the substrate 101 directly. Additional dies 108-110 may be placed on top of the die 107 in a stacked configuration. The die 107 and the dummy beams 104-106 are positioned so that a portion of each of the dummy beams 104-106 extends beyond an edge of the die 107. For example, the multiple dummy beams 104-106 and the die 107 may be placed so that the first end 112 of each dummy beam 104-106 extend beyond one edge of the die 107 and the second end 113 of each dummy beam 104-106 extend beyond an opposite edge of the die 107 as shown in FIG. 1. A similar process may be used to make the embodiment of FIG. 3.

In some cases, the package 100 having a substrate 101 may be obtained with solder balls 111 already formed on the bottom surface 103 of the substrate 101. In that case, block 520 is not necessary.

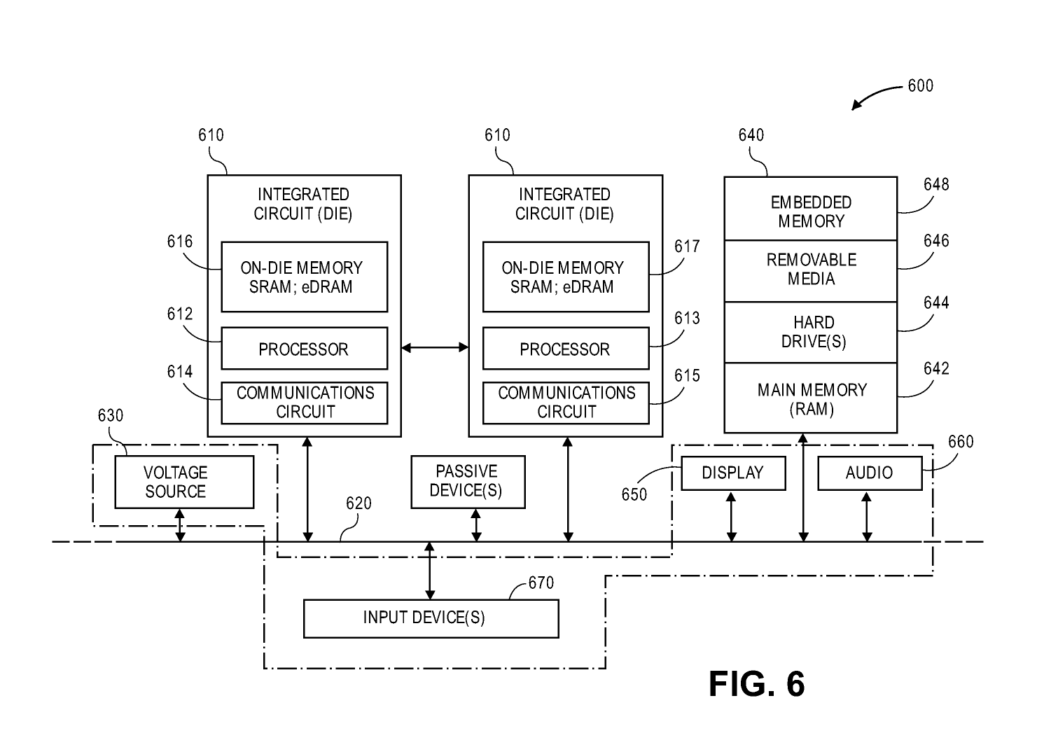

FIG. 6 illustrates a schematic of a computer system 600, in accordance with an embodiment of the present invention. The computer system 600 (also referred to as the electronic system 600) as depicted can embody a package having improved solder joint reliability through the use of dummy beams, according to any of the several disclosed embodiments and their equivalents as set forth in this disclosure. The computer system 600 may be a mobile device such as a netbook computer. The computer system 600 may be a mobile device such as a wireless smart phone. The computer system 600 may be a desktop computer. The computer system 600 may be a hand-held reader. The computer system 600 may be a server system. The computer system 600 may be a supercomputer or high-performance computing system.

In an embodiment, the electronic system 600 is a computer system that includes a system bus 620 to electrically couple the various components of the electronic system 600. The system bus 620 is a single bus or any combination of busses according to various embodiments. The electronic system 600 includes a voltage source 630 that provides power to the integrated circuit 610. In some embodiments, the voltage source 630 supplies current to the integrated circuit 610 through the system bus 620.

The integrated circuit 610 is electrically coupled to the system bus 620 and includes any circuit, or combination of circuits according to an embodiment. In an embodiment, the integrated circuit 610 includes a processor 612 that can be of any type. As used herein, the processor 612 may mean any type of circuit such as, but not limited to, a microprocessor, a microcontroller, a graphics processor, a digital signal processor, or another processor. In an embodiment, the processor 612 includes, or is coupled with, a package having improved solder joint reliability through the use of dummy beams, as disclosed herein. In an embodiment, SRAM embodiments are found in memory caches of the processor. Other types of circuits that can be included in the integrated circuit 610 are a custom circuit or an application-specific integrated circuit (ASIC), such as a communications circuit 614 for use in wireless devices such as cellular telephones, smart phones, pagers, portable computers, two-way radios, and similar electronic systems, or a communications circuit for servers. In an embodiment, the integrated circuit 610 includes on-die memory 616 such as static random-access memory (SRAM). In an embodiment, the integrated circuit 610 includes embedded on-die memory 616 such as embedded dynamic random-access memory (eDRAM).

In an embodiment, the integrated circuit 610 is complemented with a subsequent integrated circuit 611. Useful embodiments include a dual processor 613 and a dual communications circuit 615 and dual on-die memory 617 such as SRAM. In an embodiment, the dual integrated circuit 610 includes embedded on-die memory 617 such as eDRAM.

In an embodiment, the electronic system 600 also includes an external memory 640 that in turn may include one or more memory elements suitable to the particular application, such as a main memory 642 in the form of RAM, one or more hard drives 944, and/or one or more drives that handle removable media 646, such as diskettes, compact disks (CDs), digital variable disks (DVDs), flash memory drives, and other removable media known in the art. The external memory 640 may also be embedded memory 648 such as the first die in a die stack, according to an embodiment.

In an embodiment, the electronic system 600 also includes a display device 650, an audio output 660. In an embodiment, the electronic system 600 includes an input device such as a controller 670 that may be a keyboard, mouse, trackball, game controller, microphone, voice-recognition device, or any other input device that inputs information into the electronic system 600. In an embodiment, an input device 670 is a camera. In an embodiment, an input device 670 is a digital sound recorder. In an embodiment, an input device 670 is a camera and a digital sound recorder.

As shown herein, the integrated circuit 610 can be implemented in a number of different embodiments, including a package substrate having improved solder joint reliability through the use of dummy beams, according to any of the several disclosed embodiments and their equivalents, an electronic system, a computer system, one or more methods of fabricating an integrated circuit, and one or more methods of fabricating an electronic assembly that includes a package substrate having improved solder joint reliability through the use of dummy beams, according to any of the several disclosed embodiments as set forth herein in the various embodiments and their art-recognized equivalents. The elements, materials, geometries, dimensions, and sequence of operations can all be varied to suit particular I/O coupling requirements including array contact count, array contact configuration for a microelectronic die embedded in a processor mounting substrate according to any of the several disclosed package substrates having improved solder joint reliability through the use of dummy beams embodiments and their equivalents. A foundation substrate may be included, as represented by the dashed line of FIG. 6. Passive devices may also be included, as is also depicted in FIG. 6.

### Examples

The following examples pertain to embodiments.

Example 1 is a method of forming a package including placing a dummy beam on a first surface of a substrate, the substrate comprising an opposite second surface comprising contact points; and placing a die on top of the dummy beam so that the die does not contact the substrate directly.

In Example 2, the subject matter of Example 1 can optionally include wherein a portion of the dummy beam extends beyond an edge of the die.

In Example 3, the subject matter of Examples 1 or 2 can optionally include wherein the dummy beam has less rigidity than the die.

In Example 4, the subject matter of Examples 1 or 2 can optionally include wherein the dummy beam has a length greater than its width.

In Example 5, the subject matter of Example 2 can optionally include wherein a length of the dummy beam has a first end and a second end, the first end extending beyond one edge of the die and the second end extending beyond an opposite edge of the die.

In Example 6, the subject matter of Example 1 can optionally include wherein a length of the dummy beam is less than a length and a width of the substrate.

In Example 7, the subject matter of Example 1 can optionally include wherein the length of the dummy beam is greater than a length and a width of the die.

In Example 8, the subject matter of Example 1 can optionally include wherein each side of the substrate is greater in length than a length and a width of the die.

In Example 9, the subject matter of Example 1 can optionally include placing a plurality of dies stacked on top of the dummy beam.

In Example 10, the subject matter of Example 1 can optionally include placing a plurality of dummy beams on the substrate, each of the plurality of dummy beams separated from one another, and placing a die on the plurality of dummy beams comprises placing the die on a portion of each of the plurality of dummy beams.

In Example 11, the subject matter of Example 10 can optionally include wherein the plurality of dummy beams are parallel to each other.

In Example 12, the subject matter of Example 1 can optionally include wherein the dummy beam comprises a rectangle shape.

Example 13 is a package including a substrate comprising a first surface and an opposite second surface; at least one dummy beam placed on the first surface of the substrate; and a die placed on the at least one dummy beam so that the at least one dummy beam is between the die and the substrate.

In Example 14, the subject matter of Example 13 can optionally include wherein the at least one dummy beam has a length greater than its width.

In Example 15, the subject matter of Example 14 can optionally include wherein the length of the at least one dummy beam has a first end and a second end, the first end extending beyond one edge of the die and the second end extending beyond an opposite edge of the die.

In Example 16, the subject matter of Example 14 can optionally include wherein the length of the at least one dummy beam is less than a length and a width of the substrate.

In Example 17, the subject matter of Example 14 can optionally include wherein the length of the at least one dummy beam is greater than a length and a width of the die.

In Example 18, the subject matter of Example 14 can optionally include wherein a length and a width of the substrate is greater than a length and a width of the die.

In Example 19, the subject matter of Examples 13, 14, 15, 16, 17, or 18 can optionally include a plurality of dies stacked on the top surface of the dummy beam.

In Example 20, the subject matter of Example 13 can optionally include a plurality of dummy beams placed on the top surface of the substrate.

In Example 21, the subject matter of Example 20 can optionally include wherein the plurality of dummy beams are parallel to each other.

In Example 22, the subject matter of Example 13 can optionally include wherein the at least one dummy beam comprises a rectangle shape.

In Example 23, the subject matter of Example 13 can optionally include wherein a portion of the dummy beam extends beyond an edge of the die and the dummy beam has less rigidity than the die.

Example 24 is a method of forming a package including placing a plurality of dummy beams on a first surface of a substrate, the substrate comprising an opposite second surface comprising contact points; and placing a die disposed on each of the dummy beams; wherein the plurality of dummy beams are separated from one another.

In Example 25, the subject matter of Example 24 can optionally include wherein a portion of each of the plurality of dummy beams extends beyond an edge of the die and each of the plurality of dummy beams has less rigidity than the die.

In Example 26, the subject matter can optionally include an apparatus including means for performing the method of any one of Examples 1-12 and 24-25.

The above description of illustrated implementations, including what is described in the Abstract, is not intended to be exhaustive or to limit the embodiments of invention to the precise forms disclosed. While specific implementations of, and examples for, embodiments of the invention are described herein for illustrative purposes, various equivalent modifications are possible within the scope, as those skilled in the relevant art will recognize. These modifications may be made to embodiments of the invention in light of the above detailed description. For example, although the descriptions above show only a single side or surface of a package, those descriptions can apply to processing multiple adjacent packages; or a top and bottom of a single package (e.g., cored package) at one time.

The terms used in the following claims should not be construed to limit embodiments of the invention to the specific implementations disclosed in the specification and the claims. Rather, the scope is to be determined entirely by the following claims, which are to be construed in accordance with established doctrines of claim interpretation.

1.-25. (canceled)

26. A method of forming a package comprising:
placing a dummy beam on a first surface of a substrate, the substrate comprising an opposite second surface comprising contact points; and
placing a die on top of the dummy beam so that the die does not contact the substrate directly.

27. The method of claim 26, wherein a portion of the dummy beam extends beyond an edge of the die.

28. The method of claim 26, wherein the dummy beam has less rigidity than the die.

29. The method of claim 27, wherein a length of the dummy beam has a first end and a second end, the first end extending beyond one edge of the die and the second end extending beyond an opposite edge of the die.

30. The method of claim 26, wherein a length of the dummy beam is less than a length and a width of the substrate.

31. The method of claim 26, wherein the length of the dummy beam is greater than a length and a width of the die.

32. The method of claim 26, further comprising:
placing a plurality of dies stacked on top of the dummy beam.

33. The method of claim 26, further comprising:
placing a plurality of dummy beams on the substrate, each of the plurality of dummy beams separated from one another, and placing a die on the plurality of dummy beams comprises placing the die on a portion of each of the plurality of dummy beams.

34. The method of claim 33, wherein the plurality of dummy beams are parallel to each other.

35. A package comprising:
a substrate comprising a first surface and an opposite second surface;
at least one dummy beam placed on the first surface of the substrate; and
a die placed on the at least one dummy beam so that the at least one dummy beam is between the die and the substrate.

36. The package of claim 35, wherein the at least one dummy beam has a length greater than its width.

37. The package of claim 36, wherein the length of the at least one dummy beam has a first end and a second end, the first end extending beyond one edge of the die and the second end extending beyond an opposite edge of the die.

38. The package of claim 36, wherein the length of the at least one dummy beam is less than a length and a width of the substrate.

39. The package of claim 36, wherein the length of the at least one dummy beam is greater than a length and a width of the die.

40. The package of claim 36, wherein a length and a width of the substrate is greater than a length and a width of the die.

41. The package of claim 35, further comprising:
a plurality of dies stacked on the top surface of the dummy beam.

42. The package of claim 35, further comprising:
a plurality of dummy beams placed on the top surface of the substrate.

43. The package of claim 35, wherein a portion of the dummy beam extends beyond an edge of the die and the dummy beam has less rigidity than the die.

44. A method of forming a package comprising:
placing a plurality of dummy beams on a first surface of a substrate, the substrate comprising an opposite second surface comprising contact points; and
placing a die disposed on each of the dummy beams;
wherein the plurality of dummy beams are separated from one another.

45. The method of claim 44, wherein a portion of each of the plurality of dummy beams extends beyond an edge of the die and each of the plurality of dummy beams has less rigidity than the die.
